(19) United States
(12) Patent Application Publication
(10) Pub. No.: US 2006/0177773 A1
(43) Pub. Date: Aug. 10, 2006

(54) Method for producing semiconductor patterns on a wafer

(76) Inventors: Mario Hennig, Dresden (DE); Wolfram Koestler, Langebrueck (DE); Molela Moukara, Muenchen (DE); Joerg Thiele, Vaterstetten (DE); Thorsten Winkler, Muenchen (DE); Karsten Zeiler, Muenchen (DE)

Correspondence Address: SLATER & MATSIL LLP, 17950 PRESTON ROAD, SUITE 1000, DALLAS, TX, 75252, US

(21) Appl. No.: 11/335,152

(22) Filed: Jan. 19, 2006

(30) Foreign Application Priority Data
Jan. 19, 2005 (DE) 10 2005 003 183.3

(51) Int. Cl. G03F 7/00

(52) U.S. Cl. 430/311; 430/394

(57) ABSTRACT

A method is used to produce semiconductor patterns (10′, 13′) on a wafer (15′). For this purpose, a mask (25) and a dipole aperture (2) with two aperture openings (2b) arranged behind one another in a dipole axis (y) are used. The mask (25) is imaged on the wafer (15′) by means of the dipole aperture (2) and, by the imaging of the mask (25) on the wafer (15′), main semiconductor patterns (10′) are produced which are aligned perpendicularly to the dipole axis (y) and in parallel with an imaging axis (x). A second mask (35) with at least one connecting mask pattern (33) is imaged on the wafer (15′) by means of a second aperture (6), as a result of which a connecting semiconductor pattern (13) is produced on the wafer (15′), by means of which at least two of the main semiconductor patterns (10′) are connected to one another.

This application claims priority to German Patent Application 10 2005 003 183.3, which was filed Jan. 19, 2005, and is incorporated herein by reference.

### TECHNICAL FIELD

The invention relates to a method for producing semiconductor patterns on a wafer.

### BACKGROUND

It is known to produce semiconductor circuits from wafers that are exposed through a mask in such a manner that mask patterns of the mask are imaged as semiconductor patterns on the wafer. The mask patterns are usually either opaque or transparent for the light waves used in the imaging exposure. During the imaging process, the opaque mask patterns cover patterns on the wafer in such a manner that they are not illuminated. The light waves pass through transparent mask patterns during the imaging process, which is why a light incidence occurs on areas of the wafer covered by transparent mask patterns. The wafers are usually constructed in such a way that their structure changes with light incidence (for example, a layer is etched away) as a result of which semiconductor patterns are produced on the wafer during the process of imaging a mask on a wafer.

A great number of physical effects must be circumvented so that the semiconductor circuit can become smaller and smaller, more efficient or, respectively, inexpensive. In particular, constructive interference effects in the optical lithography can be circumvented in such a manner that, with a given wavelength, subwavelength circuit elements can be imaged. A dipole aperture which, instead of one opening like a conventional circular aperture has two aperture openings, is known as a particularly advantageous aperture for the imaging process from the prior art, especially from A. K. Wong, “Resolution Enhancement Techniques in Optical Lithography”, SPIE Press, vol. TT 47, March 2001, which is incorporated herein by reference. The centers of the two aperture openings define one dipole axis, which is important for the imaging characteristics of the mask on the wafer. Mask patterns that are aligned in parallel with the dipole axis are imaged differently from mask patterns that are aligned perpendicularly thereto and in parallel with an imaging axis. The dipole axis is very suitable for use during the imaging of semiconductor patterns aligned in parallel with the imaging axis. In fact, dipole apertures are usually only used for producing semiconductor circuits that exhibit almost exclusively semiconductor patterns that are aligned in parallel with one another and in the direction of imaging, the so-called main semiconductor patterns. For this purpose, main mask patterns aligned in parallel with the imaging axis are also provided on the mask.

However, the main semiconductor patterns arranged in parallel with one another must be partially connected to one another in order to provide electrical contacts between the main semiconductor patterns. However, it has been found that mask patterns that are aligned in parallel with the dipole axis are imaged only in a very poor quality as semiconductor patterns on the wafer during the imaging process.

### SUMMARY OF THE INVENTION

In one aspect, the invention provides a method of forming a wafer in such a manner that main semiconductor patterns aligned in parallel with one another are connected better to one another on a wafer. This method utilizes advantages of a dipole aperture.

According to embodiments of the invention, the wafer is exposed in two steps: in one step, with a dipole aperture as first aperture and a mask, main semiconductor patterns aligned in parallel with the imaging axis being produced on the wafer by main mask patterns of the mask, and in a second step with a second aperture and a second mask. In this arrangement, the second mask exhibits at least one connecting mask pattern as a result of the imaging thereof on the wafer a connecting semiconductor pattern is produced on the wafer. As a result, at least two of the main semiconductor patterns are connected to one another. During this process, it is not crucial whether firstly the exposure step with the dipole aperture and the mask is performed and then the imaging of the second mask by means of the second aperture, or conversely. It is crucial that the production of the wafer occurs in two steps, the main semiconductor patterns being produced on the wafer by means of a dipole aperture.

This makes it possible to fully utilize the high imaging quality of the dipole aperture. In one embodiment, mask patterns of the second mask are imaged by the second aperture in equally good quality independently of their alignment on the wafer. This means that the second aperture does not have any preferred direction (like the dipole aperture) but is constructed to be circular symmetric, for example.

It is particularly preferred to use an annular aperture, that is to say a ring-shaped aperture, as the second aperture. Between the imaging processes, the dipole aperture is exchanged for the annular aperture or conversely.

Advantageously, all main semiconductor patterns provided in the layout are produced on the wafer during the imaging of the mask by means of the dipole aperture. This optimizes the imaging quality of the main semiconductor patterns. The areas in which connecting semiconductor patterns are created during an exposure process with the second aperture and the second mask are provided preferably opaque on the first mask or with a half-tone in the case of a three-tone mask, so that both conductive and non-conductive patterns can be produced at these areas of the wafer during the second exposure process.

It has been found to be particularly advantageous in the case of three-tone masks if on the mask and/or the second mask transition edges covered with half-tone material, which are preferably formed to be wider than the main semiconductor patterns to be produced on the wafer, are formed between glass areas and areas covered with chromium. The direct transition from a glass area to an area covered with chromium is disadvantageous on a three-tone mask.

Advantageously, all connecting semiconductor patterns provided in the layout are produced during the exposure of the second mask on the wafer. In this process, the quality of the connecting semiconductor patterns is maximized since these must be aligned at least partially in parallel with the dipole axis of the dipole aperture, which is equivalent to a poor imaging quality during the exposure with the dipole aperture.

In one embodiment of the invention, a second mask is used, the connecting mask pattern of which is at least partially formed to be stepped. This shape is particularly well suited to producing the connecting semiconductor pattern since the second mask can be particularly well aligned in a direction parallel to the imaging axis with a stepped formation.

The stepped shape of the connecting mask pattern is preferably formed as a sequence of sections aligned in parallel with the dipole axis and in parallel with the imaging axis. During the production of the mask, it is technically simplest to form patterns aligned in these two directions on the mask. This is why a stepped formation of such sections is advantageous.

As an alternative, the second mask can also have a connecting mask pattern with an oblique course of a first main mask pattern with respect to a second main mask pattern.

In a preferred embodiment, a three-tone mask is used as mask for the exposure with the dipole aperture (also called dipole mask from now on). The three-tone mask exhibits main mask patterns for producing the main semiconductor patterns, the main mask patterns being covered with a half-tone layer and intermediate spaces are formed of glass. In this arrangement, areas, in which connecting semiconductor patterns are produced on exposure with the second mask, are covered with a half-tone layer in order to enable conductive and non-conductive patterns to be formed on the wafer.

Advantageously, a three-tone mask is also used as second mask in which the connecting mask pattern is covered with a half-tone layer and intermediate spaces are formed of glass. As an alternative, the mask patterns used for forming the conductive patterns can also be formed of glass when another wafer is used, and the mask patterns used for forming the non-conductive semiconductor patterns can be formed of a half-tone layer.

In a preferred embodiment, the main semiconductor patterns are formed in at least one coherent main area in the layout of the wafer. This enables a dipole mask to be implemented in a particularly simple manner.

In the layout of the wafer, at least two connecting semiconductor patterns are advantageously formed in a coherent connecting area. It is particularly preferred if all connecting semiconductor patterns provided in the layout of the wafer are arranged in a single connecting area. As a result, a second mask can be used, which is not composed of many prepared areas but the mask patterns of which are only formed in the coherent area that corresponds to the connecting area on the wafer.

In this arrangement, the connecting areas are preferably aligned in parallel with the dipole axis. Since the connecting semiconductor patterns on the wafer extend in the direction of the dipole axis and main semiconductor patterns displaced parallel to one another in the direction of the dipole axis are connected by them, this alignment of the connecting areas is a particularly space-saving arrangement.

In one embodiment, a light wavelength of about 193 nm is used both during the imaging of the mask and during the imaging of the second mask. In this context, main and connecting semiconductor patterns, which essentially are about 90 nm wide and are used in the 90 nm circuit technology, can be produced on the wafer when a dipole aperture is used. In particular, the connecting semiconductor patterns can represent outer bit line wiring arrangements that connect lines on the wafer to one another.

In another aspect, the invention is also achieved by an imaging system that, for carrying out the preceding method, consists of a dipole mask and of a dipole aperture and of a second mask and of a second aperture.

In addition, the object forming the basis of the invention is achieved by a set of masks that consist of at least one dipole mask for imaging by means of a dipole aperture, defining a dipole axis, on a wafer, and a second mask for imaging and correction of errors produced on the wafer by the imaging of the dipole mask on the wafer. In this arrangement, the dipole mask is formed in such a manner that due to the imaging of the dipole mask on a wafer, main semiconductor patterns are produced, which are aligned perpendicularly to the dipole axis and in parallel with an imaging axis perpendicular thereto. The second mask exhibits at least one connecting mask pattern as a result of which, during the imaging, a connecting semiconductor pattern is produced on the wafer by means of which at least two of the main semiconductor patterns are connected to one another.

### DESCRIPTION OF THE DRAWINGS

In the text that follows, the invention will be explained in greater detail with reference to embodiments shown in the figures, in which:

FIG. 1a shows a layout for a semiconductor circuit with main and connecting semiconductor patterns;

FIG. 1b shows a wafer image after imaging of a mask having the shape corresponding to the layout of FIG. 1a as prior art;

FIG. 2a shows the layout for a semiconductor circuit analogously to FIG. 1a;

FIG. 2b shows a dipole mask for imaging on a wafer for producing a first area of the semiconductor circuit according to FIG. 2a;

FIG. 2c shows a second mask for imaging on a wafer for producing a second area of the semiconductor circuit according to FIG. 2a;

FIG. 2d shows a wafer image with semiconductor patterns after imaging of the mask of FIG. 2b and of the second mask of FIG. 2c on the wafer;

FIG. 3a shows a diagrammatic representation of a circular aperture;

FIG. 3b shows a diagrammatic representation of a dipole aperture;

FIG. 3c shows a diagrammatic representation of an annular aperture;

FIG. 4 shows a diagrammatic representation of a three-tone substrate;

FIG. 5a shows a diagrammatic representation of a dipole mask with an unexposed area parallel to the dipole axis;

FIG. 5b shows a diagrammatic representation of a second mask with unexposed side areas and a number of connecting mask patterns in a central area;

FIG. 5c is an electron microscope recording of a section of the dipole mask from FIG. 5a;

FIG. 5d is an electron microscope recording of a section of the second mask from FIG. 5b; and

FIG. 5e is an electron microscope recording of a wafer after the imaging of the dipole mask from FIG. 5a with a dipole aperture and imaging of the second mask of FIG. 5b on the wafer.

The following list of reference symbols can be used in conjunction with the figures:
1 Circular aperture
1a Opaque area of the circular aperture
1b Transparent area of the circular aperture
2 Dipole aperture
2a Opaque area of the dipole aperture
2b Transparent area of the dipole aperture
3 Chromium
4 Half-tone material
5 Glass
6 Annular aperture
6a Opaque area of the annular aperture
6b Transparent area of the annular aperture
10 Main semiconductor pattern in the layout
11 Non-conductive area in the layout
12 Contacts in the layout
13 Connecting semiconductor pattern in the layout
15 Layout of a semiconductor circuit
10′ Main semiconductor pattern on the wafer
11′ Non-conductive area on the wafer
12′ Contacts on the wafer
13′ Connecting semiconductor pattern on the wafer
14′ Short circuit
15′, 15″ Semiconductor circuit/wafer image
20 Main mask pattern
21 Glass area
25, 25′ Dipole mask
26 Connecting area
31 Glass area
33 Connecting mask pattern
33-1 Section parallel to the dipole axis
33-2 Section parallel to the imaging axis
35, 35′ Second mask
37 Main area
38 Edges
x Imaging axis
y Dipole axis

### DETAILED DESCRIPTION OF ILLUSTRATIVE EMBODIMENTS

In the figures, mutually corresponding or similar features have the same reference symbols.

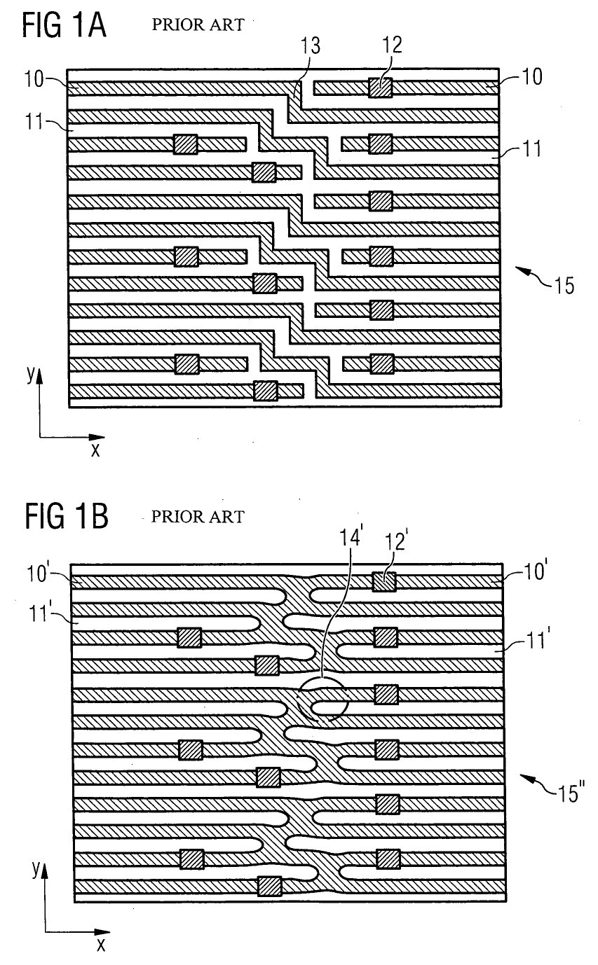

FIG. 1a shows a layout for a semiconductor circuit that consists of a number of elements, in a diagrammatic representation.

Semiconductor tracks are shown as main semiconductor patterns 10, connecting semiconductor patterns 13, contact points 12 and intermediate spaces as non-conductive areas 11.

The conductor tracks are mainly aligned along a first direction, the x direction in FIG. 1a. The x direction is the predominant imaging direction since, for producing the semiconductor circuit of FIG. 1a, a lithography mask is exposed with a dipole aperture, which achieves a particularly good imaging quality along one direction.

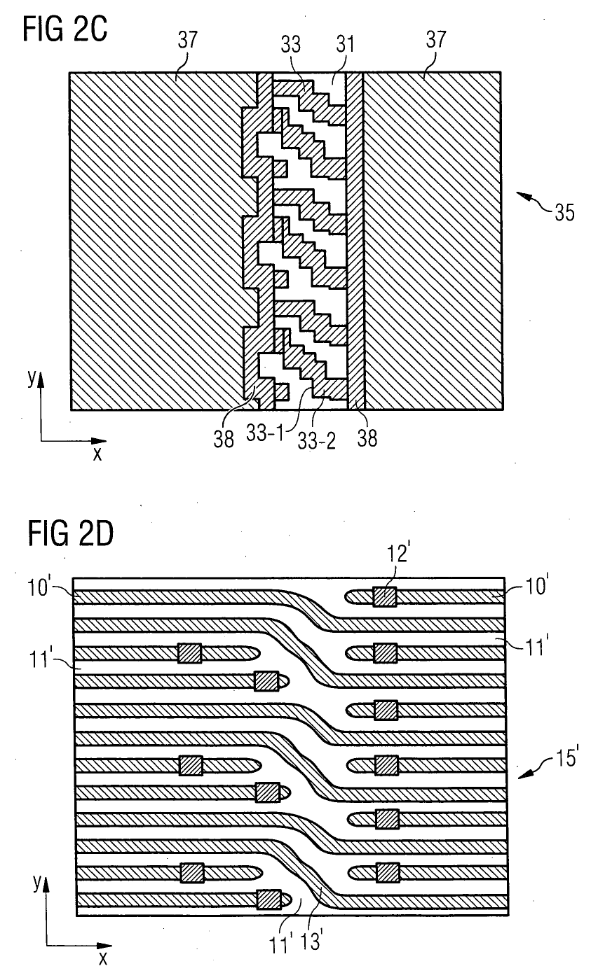

FIG. 3b shows such a dipole aperture 2 that includes an opaque area 2a in which two circular aperture openings 2b are left open. Only the circular apertures 2b are transparent whereas the area 2a is formed to be opaque. The axis defined by connecting the centers of the two aperture openings 2b is called the dipole axis y. Mask patterns aligned along this dipole axis y can only be imaged in very poor quality on a wafer by means of a dipole aperture. The imaging axis x extends perpendicularly to the dipole axis y. Mask patterns aligned in parallel with the imaging axis x, i.e., “in imaging direction,” are imaged in particularly good quality by a dipole aperture 2.

The aperture openings 2b of the dipole aperture 2 do not need to be formed to be precisely circular in this arrangement. It is essential that the dipole aperture 2 has two aperture openings. Depending on the semiconductor patterns to be produced, these can also be half-moon-shaped or provided with aperture openings with serrated boundaries.

Compared with a conventional circular aperture 1, shown in FIG. 3a, with an opaque area 1a in which a single circular opening 1b is used as aperture, the dipole aperture 2 achieves a better quality during the imaging of mask patterns aligned in the imaging direction x and a poorer quality in the aperture opening direction y.

This is the reason why most of the semiconductor patterns of the layout in FIG. 1a are aligned in parallel with the imaging axis x and, therefore, extend parallel to one another. Semiconductor patterns aligned in parallel with the imaging axis are called main semiconductor patterns 10. In the semiconductor circuit, the layout of which is shown by FIG. 1a, the main semiconductor patterns 10 are to be formed to be conductive and are separated from one another by non-conductive areas 11. The non-conductive areas 11 correspond to the spaces between the conductive areas of the semiconductor circuit, such as, e.g., the main semiconductor patterns 10 and the contacts 12.

To provide connections between the various main semiconductor patterns 10, individual connecting semiconductor patterns 13 extend perpendicularly to the main semiconductor patterns 10 and in parallel with the dipole axis. The connecting semiconductor patterns 13 are intended to provide electrical contacts between the main semiconductor patterns 10.

Depending on the function of the semiconductor circuit, various localized contacts 12 are provided on the layout, which are provided for contacting the semiconductor circuit with electrical elements or lines, not shown. To produce a semiconductor circuit having the layout of FIG. 1a, a mask is exposed on a wafer, using a dipole aperture like the dipole aperture 2 from FIG. 3b for this purpose. In the prior art, the masks used for this purpose have the same layout as the semiconductor circuits to be produced. Accordingly, the conductive patterns (that is to say the main semiconductor patterns 10 and connecting semiconductor patterns 13) correspond to opaque patterns on a mask and the non-conductive areas 11 on the semiconductor circuit correspond to transparent patterns on the mask. As an alternative, it is also possible to allocate transparent areas on the mask to the conductive semiconductor patterns whereas opaque areas on the mask are allocated the non-conductive areas, depending on the type of lithography.

Using a mask that exactly corresponds to the layout of FIG. 1a, a semiconductor circuit corresponding to the wafer image of FIG. 1b is produced as wafer image by means of a dipole aperture during the imaging of the mask on a wafer. Although the main semiconductor patterns 10′ are formed well in the semiconductor circuit of FIG. 1b, the connecting semiconductor patterns 13′ are formed widened. As a result, contacts are produced between semiconductor patterns on the semiconductor circuit, which were not provided in the layout of FIG. 1a. For example, the sections of the semiconductor circuit of FIG. 1b marked with a circle exhibit short circuits 14′ between individual main semiconductor patterns 10′. Such short circuits 10′ lead to malfunctions of the semiconductor circuit.

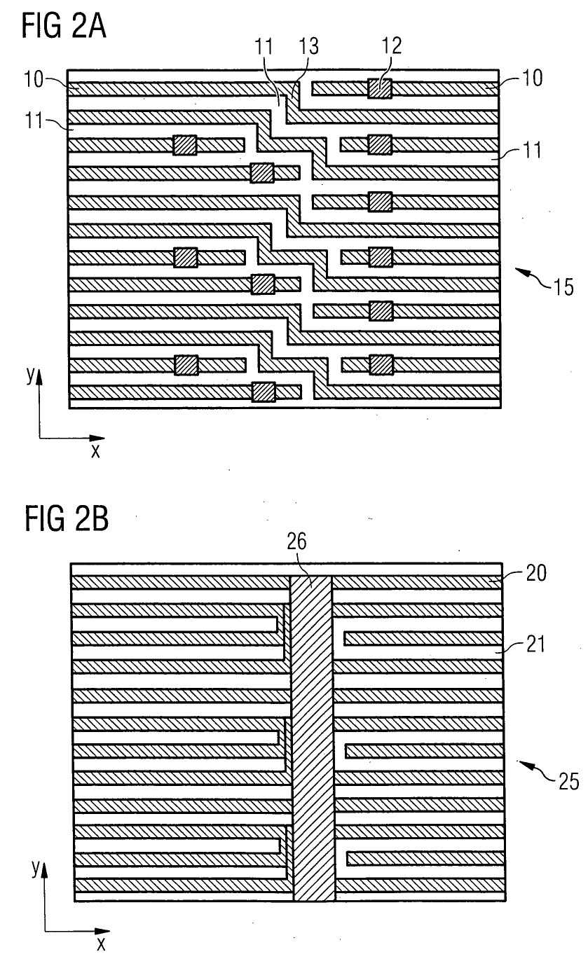

The invention will now be explained with reference to FIGS. 2a, 2b, 2c and 2d. FIG. 2a shows the layout 15 of a semiconductor circuit, which corresponds to the layout of FIG. 1a. In the layout 15, main semiconductor patterns 10, connecting semiconductor patterns 13, contacts 12 and non-conductive areas 11 are shown.

However, it is not a mask that is complementary to the layout 15 that is used for the imaging but, according to the invention, firstly the dipole mask 25, shown in FIG. 2b as a mask for an exposure with the dipole aperture 2 (compare FIG. 3b) and the second mask 35, shown in FIG. 2c, for exposure by means of an annular aperture (compare FIG. 3c).

In the layout of the dipole mask 25 from FIG. 2b, main mask patterns 20 are provided for forming the main semiconductor patterns 10 of the layout 15 (see FIG. 2a). At the position of the electrical contacts 12 in the layout 15, no separate patterns are provided on the dipole mask 25. At the positions allocated to the electrical contacts 12, main mask patterns 20 are formed in the dipole mask 25. To produce the non-conductive areas 11, glass areas 21 are provided on the dipole mask 25. In the areas in which main semiconductor patterns 10 are provided only locally in the layout 15, the layout of the dipole mask 25 corresponds one to one to the layout 15 from FIG. 2a. In these areas, both the main mask patterns 20 and the intermediate glass areas 21 are aligned in parallel with the imaging axis x. The electrical contacts 12 are fixed points in the layout 15 of FIG. 2a, at the position of which in the dipole mask 25 main semiconductor patterns 10 are provided.

However, a coherent area in the center of layout 15 was changed compared with the layout 15. In this area, all connecting semiconductor patterns 13 provided in the layout are arranged so that this area could also be called connecting area 26. Apart from the connecting area 26, all patterns on the dipole mask 25 are formed in parallel with the imaging axis, which produces good imaging quality during the exposure. This coherent connecting area 26 is covered completely with the same layer as the main mask patterns 20 in the dipole mask 25. The connecting area 26 is also free of glass areas 21.

During the imaging of the dipole mask 25 onto a wafer, the areas on the wafer onto which the main mask patterns 20 and the connecting area 26 are imaged, are not changed. It is only the areas on the wafer that are allocated to the glass areas 21 that are changed during the exposure by light irradiation so that they become non-conductive areas 11. However, since no glass areas 21 are arranged in the connecting area 26, the wafer can still be completely patterned in this area by the second exposure process with the second mask 35 from FIG. 2c.

In a second exposure step, the second mask 35 is imaged on the same wafer. During the second imaging process, an annular aperture is used as shown in FIG. 3c. In an opaque area 6a, a ring-shaped annular aperture 6b is formed through which light waves radiate during the exposure of the second mask 35.

The connecting area 26 of the dipole mask 25 is thus used for the controlled production of short circuits on the associated wafer, which are corrected by the exposure of the second mask 35 shown in FIG. 2c.

If, instead of the dipole mask 25, a mask corresponding to the layout of FIG. 1a were to be used for the first exposure process, uncontrolled short circuits 14′ could occur in the wafer image as shown in FIG. 1b, which would be more difficult to correct than the short circuits produced under controlled conditions by exposure of the dipole mask 25. In addition, a correction mask for the second exposure would have to have very small patterns, which reduces the size of the process window for the second exposure and would thus impair the adjustment of the second mask.

Thus, it is especially the combination of the dipole mask 25 with the second mask 35 that is particularly advantageous and, moreover, simple to implement.

The major part of the layout of the second mask 35 is opaque. These are the areas in which the main semiconductor patterns 10 are provided in the layout 15, which is why these coherent areas are also called main areas 37. It is only at the position of the connecting area 26 of the dipole mask 25 that mask patterns are formed in the second mask 35. These are connecting mask patterns 33, which are to provide the connecting semiconductor patterns 13 in the layout 15 after the imaging of the second mask 35 on the wafer. The connecting mask patterns 33 are not aligned in parallel with the dipole axis y (as in the layout 15 of FIG. 2a) but exhibit a stepped shape. The steps are formed in such a manner that they lead from a first main semiconductor pattern 10 generated by imaging the dipole mask 25 to a main semiconductor pattern 10 offset from the latter in parallel.

In the connecting area, both glass areas 31 for forming the non-conductive areas 11 on the wafer and connecting mask patterns 33 are formed on the second mask 35.

The connecting mask patterns 33 are composed of mask patterns 33-1 extending in parallel with the dipole axis y and mask patterns 33-2 aligned in parallel with the imaging axis x. Since the annular aperture does not have a preferred direction in the imaging, all mask patterns formed on the second mask are imaged in the same quality independently of their alignment. The stepped connecting mask patterns 33 are particularly well suited for adjusting the second mask in the direction parallel to the imaging axis x.

The edges 38 of the opaque main areas 37 of the second mask 35 are patterned like the connecting mask patterns 33. As a result, they are not changed during the imaging process of the second mask 35 in the areas on the wafer allocated to the edges 38. In addition, a direct transition from glass (glass area 31) to chromium (main area 37) is avoided on the second mask 35, which would have a poor imaging quality with the dimensions used. It has been found that with a wavelength of about 193 nm and semiconductor patterns with extents of approximately 90 nm, an edge 38 of half-tone of at least 100 nm distinctly reduces the imaging quality compared with a direct chromium-glass-transition on the mask. As a result, the process window is increased for the second exposure.

Sections 33-1 and 33-2 are here formed in parallel with the imaging axis x and with the dipolar axis y since it is simplest to produce mask patterns on the second mask 35 in these directions. In principle, the sections 33-1 and 33-2 of the connecting mask pattern 33 can also be arranged at other angles with respect to one another.

FIG. 2d shows semiconductor patterns in a wafer image 15′, which were produced by images of the dipolar mask 25 from FIG. 2b and the second mask 35 of FIG. 2c. The main semiconductor patterns 10′, which were imaged by the main mask patterns 20 of the dipolar mask 25 are imaged almost precisely as planned in layout 15. The non-conductive areas 11′ and contacts 12′ were also reproduced well by the corresponding mask areas of the dipolar mask 25.

In the wafer image 15′, the stepped connecting mask patterns 33 of the second mask 35 are imaged as oblique connecting semiconductor patterns 13′. The average slope of the connecting semiconductor patterns 13′ essentially corresponds to the average slope of the stepped connecting mask patterns 33 of the second mask 35. The connecting semiconductor patterns 13′, however, no longer show a stepped shape but exhibit an essentially smoothed shape. Furthermore, the connecting semiconductor patterns 13′ are formed to be slightly wider than the main semiconductor patterns 10′. The width of the main semiconductor patterns 10′ approximately corresponds to 90 nm when using a light source with a wavelength of about 193 nm. The width of the semiconductor patterns corresponds to the minimum width, which can still be generated in acceptable quality on the wafer by using the wavelength intended for imaging.

In the exemplary embodiment shown in FIG. 2d, the non-conductive areas 11′ also have a width of about 90 nm. The connecting semiconductor patterns 13′ can have fluctuations in width of up to 20% without influencing the operation of the semiconductor circuit.

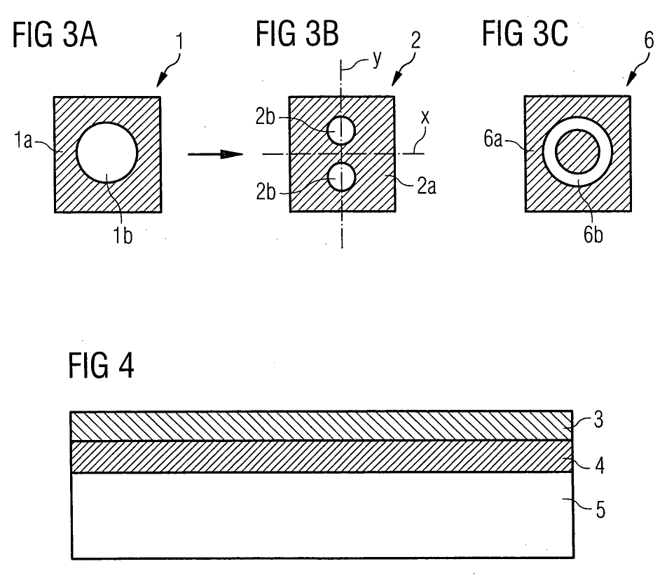

FIG. 4 shows a three-tone substrate that is used for producing a three-tone mask. The lowermost and widest layer of the three-tone substrate consists of glass 5. Above that, a half-tone layer 4 is formed which, for example, consists of MoSi. Above that, an opaque chromium layer 3 is formed as the topmost layer. Depending on whether a conductive pattern, a non-conductive pattern or a contact area is to be generated by the area of the mask, the position allocated to this area on the three-tone mask is not etched at all, is freed of the chromium layer or is etched free down to the glass layer.

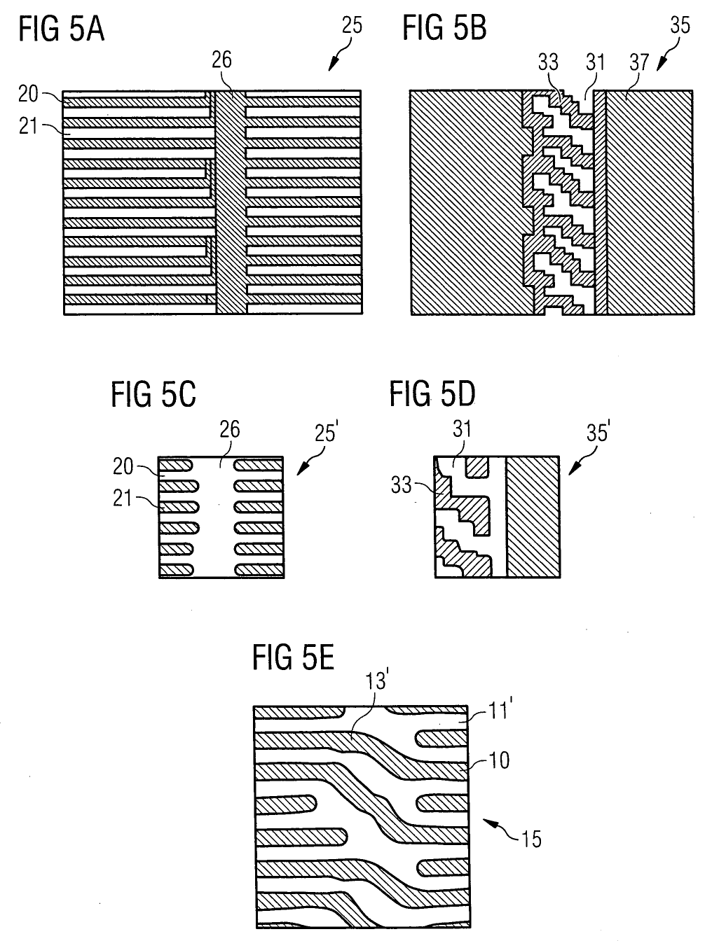

FIGS. 5a and 5b again show the dipole mask 25 and the second mask 35, which are formed as three-tone masks. The glass areas 21 of the dipole mask 25 and the glass areas 31 of the second mask 35 only consist of one glass layer 5 (compare FIG. 4). The main mask patterns 20 and the connecting area 26 of the dipole mask 25 and the stepped connecting mask patterns 33 and the edges 38 are formed as glass layer 5 on which a half-tone layer 4 is also arranged (compare FIG. 4). The main areas 37 of the second mask 35 thus consist of glass 5, of half-tone 4 and of chromium 3.

FIGS. 5c and 5d are diagrammatic sketches of electron microscope recordings, FIG. 5c showing a section from the dipole mask 25 of FIG. 5a, FIG. 5d showing a section from the second mask 35 of FIG. 5b, FIG. 5e showing the result of a production process of a wafer 15′ after exposure of both masks. FIG. 5e shows that the width of the connecting semiconductor patterns 13′ only varies within an acceptable range.

The dipole mask 25 is constructed for exposure by means of a dipole aperture, but can also be exposed by means of an annular aperture.

The main semiconductor patterns 10′ are formed as metal track on the wafer 15′, the connecting semiconductor patterns 13′ provide outer bit line wiring arrangements.

What is claimed is:

1. A method for forming a semiconductor device, the method comprising:
providing a first mask and a first aperture, the first aperture comprising a dipole aperture with two aperture openings arranged adjacent to one another along a dipole axis;
providing a second mask and a second aperture;
imaging a semiconductor wafer using the first mask and the first aperture such that main patterns are produced on the semiconductor wafer, the main patterns being aligned substantially perpendicular to the dipole axis and substantially in parallel with an imaging axis; and
imaging the semiconductor wafer with the second mask and the second aperture such that a connecting mask pattern is produced on the wafer, wherein at least two of the main semiconductor patterns are connected to one another by the connecting mask pattern.

2. The method as claimed in claim 1, wherein the connecting mask pattern of the second mask is imaged on the wafer by the second aperture, independently of alignment.

3. The method as claimed in claim 2, wherein the second aperture comprises a circular symmetric aperture.

4. The method as claimed in claim 3, wherein the second aperture comprises an annular aperture.

5. The method as claimed in claim 1, wherein all main patterns provided in a layout are produced on the wafer during the imaging of the wafer with the first mask and the first aperture.

6. The method as claimed in claim 1, wherein all connecting patterns provided in a layout are produced on the wafer during the imaging of the wafer with the second mask and the second aperture.

7. The method as claimed in claim 1, wherein the connecting mask pattern comprises at least partially stepped patterns.

8. The method as claimed in claim 7, wherein the connecting mask pattern comprises a plurality of sections that are aligned in parallel with the dipole axis and in parallel with the imaging axis.

9. The method as claimed in claim 1, wherein the connecting mask pattern extends obliquely with respect to the imaging axis.

10. The method as claimed in claim 1, wherein the connecting mask pattern on the second mask is formed from a first area to a second area, the first area on the mask being allocated to one end of a first main mask pattern for imaging by means of the dipole aperture and the second area being allocated to the end of a second main semiconductor pattern.

11. The method as claimed in claim 1, wherein the first mask comprises a three-tone mask, the main mask patterns being covered with a half-tone layer and intermediate spaces being formed of glass.

12. The method as claimed in claim 11, wherein the second mask comprises a three-tone mask, the connecting mask pattern being covered with a half-tone layer and intermediate spaces being formed of glass.

13. The method as claimed in claim 12, wherein edges that are formed to be wider than the main semiconductor patterns to be produced on the wafer are formed on the second mask between glass areas and areas covered with an opaque layer.

14. The method as claimed in claim 12, wherein edges covered with half-tone material, which are formed to be wider than the main semiconductor patterns to be produced on the wafer, are formed on the first mask and the second mask between glass areas and areas covered with an opaque layer.

15. The method as claimed in claim 1, wherein the main semiconductor patterns are provided in at least one coherent main area in a layout of the wafer.

16. The method as claimed in claim 1, wherein at least two connecting semiconductor patterns are provided in a coherent connecting area in a layout of the wafer.

17. The method as claimed in claim 16, wherein the connecting areas are provided in parallel with the dipole axis.

18. The method as claimed in claim 1, wherein areas in which the connecting mask patterns are formed in the second mask, are formed to be opaque on the first mask.

19. The method as claimed in claim 1, wherein the main pattern and the connecting pattern are used to produce semiconductor structures on the wafer, the semiconductor structures being now more than about 90 nm wide.

20. The method as claimed in claim 1, wherein imaging the semiconductor wafer with the first mask and with the second mask both comprise imaging using radiation having a wavelength of about 193 nm.

21. The method as claimed in claim 1, wherein an outer bit line wiring arrangement is produced on the wafer as connecting semiconductor pattern.

22. An imaging system for the production of semiconductor patterns on a wafer, the imaging system comprising:
a dipole aperture that includes two aperture openings arranged adjacent to one another along a dipole axis;
a first mask with mask patterns for producing main semiconductor patterns on the wafer by imaging the mask on the wafer using the dipole aperture, wherein the mask includes main mask patterns in parallel with an imaging axis that extends perpendicularly to the dipole axis,
a second aperture; and
a second mask with at least one connecting mask pattern for imaging by means of the second aperture on the wafer.

23. A set of masks comprising at least one dipole mask for imaging by means of a dipole aperture, defining a dipole axis on a wafer and a second mask for imaging and correction of errors created on the wafer by the imaging of the dipole mask on the wafer;
the dipole mask being formed in such a manner that main semiconductor patterns, which are aligned perpendicularly to the dipole axis and in parallel with an imaging axis perpendicular to the dipole axis, are produced by the imaging of the dipole mask on a wafer; and
the second mask exhibiting at least one connecting mask pattern, as a result of which, during the imaging, a connecting semiconductor pattern is produced on the wafer by means of which at least two of the main semiconductor patterns are connected to one another.
